(19) United States
(12) Patent Application Publication
(10) Pub. No.: US 2014/0217613 A1
(43) Pub. Date: Aug. 7, 2014

(54) INTEGRATED DEVICE AND FABRICATION PROCESS THEREOF

(71) Applicant: O2MICRO INC., Santa Clara, CA (US)

(72) Inventors: Marian UDREA-SPENEA, Campbell, CA (US); Viorel Alexandru MARINESCU, San Jose, CA (US); Yu Hsien CHUANG, Zhubei City (TW)

(73) Assignee: O2MICRO INC., Santa Clara, CA (US)

(21) Appl. No.: 13/757,183

(22) Filed: Feb. 1, 2013

(51) Int. Cl. H01L 23/28; H01L 21/56

(52) U.S. Cl. CPC H01L 23/28; H01L 21/56
USPC 257/777; 438/109

(57) ABSTRACT

An integrated device includes a die attach pad, a main die, a stacked die, and a mold compound. The main die has a first (e.g., bottom) surface attached to the die attach pad and has a second (e.g., top) surface. The stacked die is attached to the second surface of the main die using, for example, an adhesive film. The main die and the stacked die include silicon crystal. The mold compound encapsulates the die attach pad, the main die, and the stacked die.

### BACKGROUND

FIG. 1A shows a cross-sectional diagram of a conventional integrated device 100. As shown in FIG. 1A, the integrated device 100 includes a silicon die 102 attached to a metallic platform 106 via adhesive material 104, includes plastic molding material 108 encapsulating the silicon die 102, and includes conductive pins 120 coupled to the silicon die 102 via bonding wires 118. The silicon die 102 includes integrated circuits 112 and 114, e.g., metal-oxide-semiconductor field-effect transistors (MOSFETs), operational amplifiers, band-gap reference circuits, etc. The integrated circuits 112 and 114 are located near a surface 116 of the silicon die 102.

FIG. 1B shows an enlarged view of a portion 110 of the integrated device 100. As shown in FIG. 1B, the plastic molding material 108 includes harder particles 122 and softer material constituents 124. The particles 122 are distributed unevenly in the plastic molding material 108, and some particles 122 touch the surface 116 of the silicon die 102. Circuits in different areas of the silicon die 102 may experience different/uneven pressure because of the unevenly distributed particles 122. The uneven pressure may cause errors or offsets in parameters (e.g., voltage thresholds, voltage references, input voltages, etc.) of the integrated circuits 112 and 114.

By way of example, after the circuits 112 and 114 are formed on the silicon die 102 and before the silicon die 102 is encapsulated, some parameters of the circuits 112 and 114 may be tested. This test can be referred to as a “wafer level test.” If the test result shows that the circuits 112 and 114 can operate normally as expected, then the silicon die 102 is encapsulated by the plastic molding material 108. Because the plastic molding material 108 is applied to the silicon die 102 at a high temperature and will shrink when it is cooled to room temperature, the surface 116 may be subject to contraction forces, including compression stress and shear stress, from the plastic molding material 108. The contraction forces applied to the surface 116 are uneven and can cause errors in some parameters of the circuits 112 and 114. For example, as shown in FIG. 1B, the circuit 112 may be located in an area touched by particles 122, and the circuit 114 may be located in an area that is not touched by a particle 122. Thus, the particles 122 may apply extra pressure to the circuit 112. Although the circuits 112 and 114 may be supposed to behave identically, instead they may have different parameter values after encapsulation due to the unevenly distributed particles 122. Additionally, during mass-production, multiple integrated devices 100 which are supposed to be identical may have different parameter values or different performance characteristics due to the randomly distributed particles 122.

Thus, parameter values of circuits, e.g., operational amplifiers, band-gap reference circuits, etc., which are sensitive to pressure applied to the surface 116 may change after encapsulation. These parameters can be re-adjusted in a final test, referred to as a “trimming process.” In order to perform the trimming process, additional blocks on the silicon die 102 and additional conductor pins 120 connected to those blocks are needed. The additional blocks and conductor pins increase costs and also increase the size of the integrated device 100. Moreover, the contraction forces and uneven pressure may cause a defect in the integrated device 100. If the test result shows a defect in the integrated device 100, then either the integrated device 100 is discarded, which is wasteful, or the plastic molding material 108 is etched away to expose the silicon die 102, and the silicon die 102 is tested at the wafer level again, which is time-consuming.

Furthermore, during operation of the integrated device 100, the surface 116 may have a significant temperature gradient because, for example, the plastic molding material 108 has a very low thermal conductivity. For example, FIG. 1C shows a plot of temperature gradients on the surface 116. In FIG. 1C, a high-power circuit 130, e.g., an amplifier circuit, produces heat at position P2 of the surface 116. The heat may not dissipate quickly, and therefore a steep temperature gradient may exist on the surface 116, e.g., from position P2 to position P3. The temperature gradient, e.g., the differences in temperature at positions P1, P2, and P3 on the surface 116, may affect the performance of the integrated circuits on the silicon die 102.

FIGS. 2A and 2B, FIG. 3, FIG. 4, and FIGS. 5A and 5B show conventional integrated devices that attempt to solve the above mentioned problems. However, none of these integrated devices solves all of those problems, and some of these integrated devices may introduce additional problems.

FIG. 2A and FIG. 2B show cross-sectional diagrams of conventional integrated devices 200A and 200B. In the integrated device 200A, a die coat layer 226, with a modulus of elasticity and/or thermal expansion coefficient lower than that of the plastic molding material 108, is formed on the surface 116 to act as a buffer or stress relief layer between the plastic molding material 108 and the surface 116. The die coat layer 226 can relieve the above mentioned compression stress and uneven pressure from the plastic molding material 108 and avoid the shear stress between the plastic molding material 108 and the surface 116.

However, conventional materials used for the die coat layer 226 include silicone polymers or polyimide which may have low thermal conductivities. Thus, significant temperature gradients may exist on the surface 116 in the integrated device 200A.

In addition, the plastic molding material 108 and the die coat layer 226 have different thermal expansion coefficients. Thus, if the die coat layer 226 covers the entire surface 116, then thermal expansion or contraction of the plastic molding material 108 and the die coat layer 226 during the encapsulation process may produce a shear force that damages or severs the bonding wire 118 at the interface 230 between the plastic molding material 108 and the die coat layer 226. Moreover, as shown in FIG. 2A, the die coat layer 226 is not level. Thus, if the size of the silicon die 102 increases, then the height of the die coat layer 226 increases and the minimum thickness D1 of the plastic molding material 108 decreases. As a result, the mechanical strength of the plastic molding material 108 decreases, particularly at the point of minimum thickness.

If the die coat layer 226 is deposited in certain areas, e.g., as shown in FIG. 2B, so that the aforementioned shear force can be avoided, then almost the entire contraction vertical pressure coming from the top molding material 108 is supported by the small uncovered area(s) of the silicon die 102. This creates a large gradient in the vertical pressure applied to the silicon die 102, e.g., at points 240. The pressure may be very large on uncovered areas and it may be much lower on covered areas. This can cause damage to the top layers of the silicon die 102, e.g., at points 240. Similarly, a large pressure may be placed on areas where the die coat layer 226 is very thin, e.g., the area 250, because of poor wettability of the die coat material.

FIG. 3 shows a cross-sectional diagram of another conventional integrated device 300. In the integrated device 300, a thin and uniform layer of silicone polymer material 326 is deposited on the surface 116, using a specific process. The die coat layer 326, to some extent, can relieve the compression stress and shear stress caused by contraction of the plastic molding material 108. However, the die coat layer 326 is thin and soft, and therefore the surface 116 in the integrated device 300 may still experience uneven pressure from the harder particles 122 described in FIG. 1B. Additionally, significant temperature gradients may still exist on the surface 116 due to the low temperature conductivities of the die coat layer 326 and the plastic molding material 108. Moreover, the die coat layer 326 is soft and may have weak adhesion to the plastic molding material 108, which may allow moisture to penetrate into the plastic molding material 108 and also may reduce the mechanical strength of the package.

FIG. 4 shows a cross-sectional diagram of another conventional integrated device 400. In the integrated device 400, a die coat layer 426 made of transparent polymers is formed on the surface 116. The die coat layer 426 is formed by depositing an amount of specific liquid material, e.g., a photosensitive negative-tone transparent viscous room-temperature liquid material, on the surface 116, spinning the silicone die 102 to produce a thin and relatively flat liquid layer, and using a photomask to selectively expose the liquid layer to ultraviolet (UV) light. The exposed part of the liquid layer turns into silicone polymers. The non-exposed part is etched away to form openings 428A and 428B to protect the bonding wires 118 from shear forces caused by expansion/contraction of the plastic molding material 108 and the die coat layer 426. The die coat layer 426 may relieve some of the compression stress and shear stress caused by the contraction of the plastic molding material 108. However, the die coat layer 426 is thin and may be soft, and therefore the surface 116 in the integrated device 400 may still experience uneven pressure from the harder particles 122 discussed in FIG. 1B. Significant temperature gradients may still exist on the surface 116 in the integrated device 400. Additionally, the formation of the die coat layer 426 requires extra processes such as photomasking, UV projecting, and etching, which increase the cost of the integrated device 400.

FIG. 5A shows a cross-sectional diagram of another conventional integrated device 500, and FIG. 5B shows a top view of the integrated device 500. In the integrated device 500, a stress relief structure 526 is formed overarching the silicon die 102. Materials for the stress relief structure 526 include ceramic, silicon, an alloy, etc. The stress relief structure 526 may relieve some of the compression stress and shear stress applied to the four corners of the silicon die 102 and part of the surface 116 covered by the stress relief structure 526. The stress relief structure 526 may also serve as a heat sink to reduce temperature gradients on the surface 116. However, since the stress relief structure 526 overarches the surface 116 but does not shield it from the plastic molding material 108, uneven pressure caused by the harder particles 122 may exist on the surface 116. Additionally, the fabrication of the stress relief structure 526 is relatively difficult and expensive.

### SUMMARY

In one embodiment, an integrated device includes a die attach pad, a main die, a stacked die, and a mold compound. The main die has a first (e.g., bottom) surface attached to the die attach pad and has a second (e.g., top) surface. The stacked die is attached to the second surface of the main die using, in one embodiment, an adhesive film. The main die and the stacked die include silicon crystal. The mold compound encapsulates the die attach pad, the main die, and the stacked die.

### BRIEF DESCRIPTION OF THE DRAWINGS

Features and advantages of embodiments of the claimed subject matter will become apparent as the following detailed description proceeds, and upon reference to the drawings, wherein like numerals depict like parts, and in which:

FIG. 1A shows a cross-sectional diagram of an integrated device according to the prior art.

FIG. 1B shows an enlarged view of a portion of the integrated device of FIG. 1A.

FIG. 1C is a plot of temperature gradients at a surface of a silicon die in the integrated device of FIG. 1A according to the prior art.

FIG. 2A shows a cross-sectional diagram of another integrated device according to the prior art.

FIG. 2B shows a cross-sectional diagram of another integrated device according to the prior art.

FIG. 3 shows a cross-sectional diagram of another integrated device according to the prior art.

FIG. 4 shows a cross-sectional diagram of another integrated device according to the prior art.

FIG. 5A shows a cross-sectional diagram of another integrated device according to the prior art.

FIG. 5B shows a top view of the integrated device of FIG. 4A according to the prior art.

FIG. 6A shows a cross-sectional diagram of an example of an integrated device, in an embodiment according to the present invention.

FIG. 6B shows an example of a top view of the integrated device of FIG. 6A, in an embodiment according to the present invention.

FIG. 6C is a plot of temperature gradients at a surface of a main die in the integrated device of FIG. 6A according to the present invention.

FIG. 7A and FIG. 7B illustrate examples of fabrication steps for an integrated device, in accordance with one embodiment of the present invention.

### DETAILED DESCRIPTION

Reference will now be made in detail to the embodiments of the present invention. While the invention will be described in conjunction with these embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

Some portions of the detailed descriptions that follow are presented in terms of procedures, logic blocks, processing, and other symbolic representations of operations for fabricating semiconductor devices. These descriptions and representations are the means used by those skilled in the art of semiconductor device fabrication to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing terms such as “attaching,” “encapsulating,” “fabricating,” “cutting,” “forming,” “polishing” or the like, refer to actions and processes of semiconductor device fabrication.

Furthermore, other fabrication processes and steps may be performed along with the processes and steps discussed herein; that is, there may be a number of processes and steps before, in between and/or after the steps shown and described herein. Importantly, embodiments of the present invention can be implemented in conjunction with these other processes and steps without significantly perturbing them. Generally speaking, the various embodiments of the present invention can replace portions of a conventional process without significantly affecting peripheral processes and steps.

It is understood that the figures are not drawn to scale, and only portions of the structures depicted, as well as the various layers that form those structures, may be shown.

Embodiments according to the present invention provide an integrated device and a method for fabricating such a device. In the integrated device, the above-mentioned compression stress is reduced, the shear stress is avoided/eliminated, and the temperature gradients are flattened/reduced, using a relatively low-cost, time-saving, and environment-friendly method.

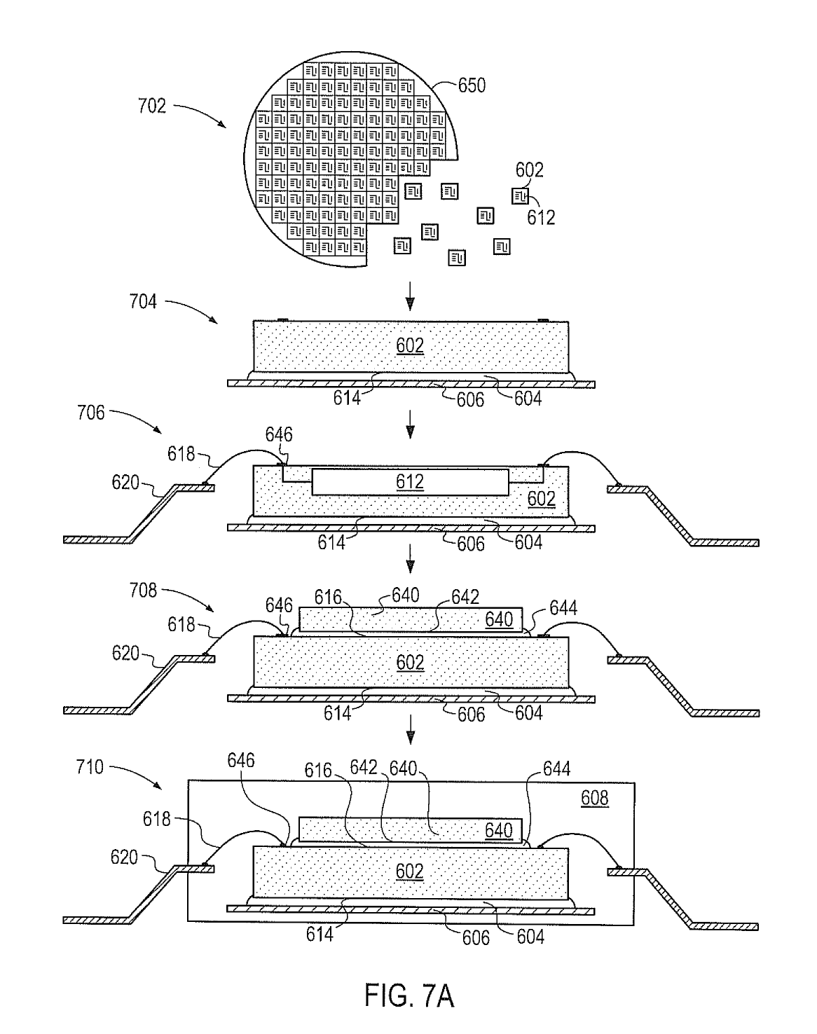

FIG. 6A shows a cross-sectional diagram of an example of an integrated device 600, and FIG. 6B shows an example of a top view of the integrated device 600, in embodiments according to the present invention. As shown in FIG. 6A, the integrated device 600 includes conductive pins 620 and an encapsulated object 610 coupled to the conductive pins 620. The encapsulated object 610 includes a die attach pad 606, a main die 602, a stacked die 640, and a mold compound 608. The main die 602 has a first surface 614 that is attached (e.g., glued) to the die attach pad 606 using, in one embodiment, an adhesive material 604, and the main die 602 has a second surface 616. Generally speaking, the surface 616 (referred to hereinafter as the top surface) is opposite (faces away from) the surface 614 (referred to hereinafter as the bottom surface). The stacked die 640 is attached to/stacked on the top surface 616 of the main die 602 using, in one embodiment, an adhesive film 644. The mold compound 608 encapsulates the die attach pad 606, the main die 602, and the stacked die 640. In addition, the integrated device 600 includes integrated circuitry 612 formed in the main die 602 and beneath the top surface 616 of the main die 602 (between the top surface 616 and the bottom surface 614). The stacked die 640 overlays the integrated circuitry 612 and can shield the integrated circuitry 612 from the mold compound 608. The conductive pins 620 are connected to the integrated circuitry 612 via, e.g., conductive pads 646 and bonding wires 618.

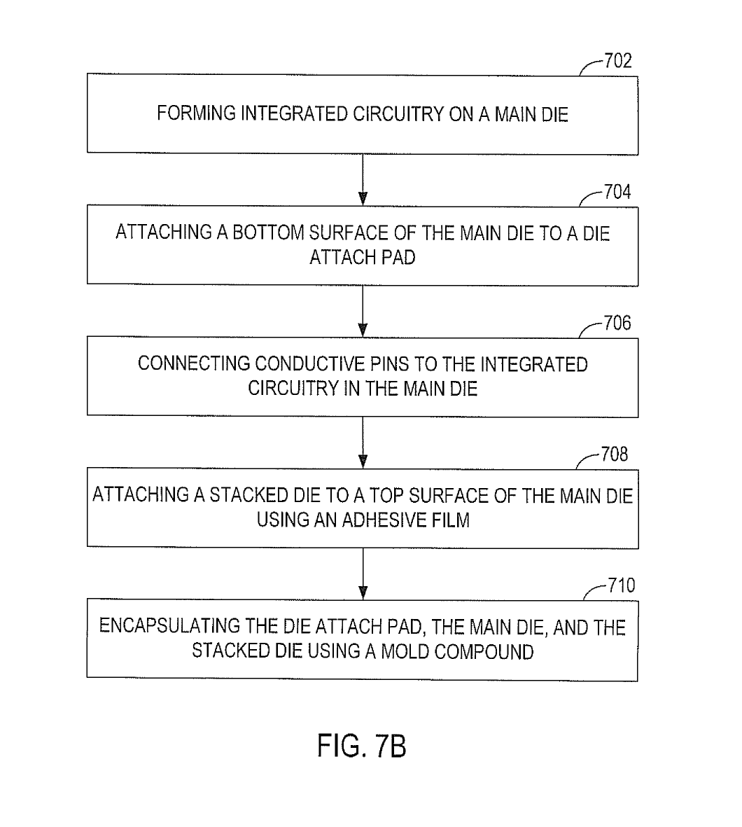

More specifically, in one embodiment, polycrystalline silicon is melted to grow silicon crystals in, e.g., cylindrical ingots, and the silicon crystals are sliced into silicon wafers. The main die 602 is fabricated from a silicon wafer, e.g., the silicon wafer 650 shown in FIG. 7A. The die attach pad 606 can be, but is not limited to, a metallic pad, e.g., a copper pad, an aluminum pad, etc., and can be used as a base to support the main die 602. The adhesive film 644, for attaching/gluing the stacked die 640 to the main die 602, includes electrically non-conductive adhesive material such as epoxy resin. The adhesive film 644 can be relatively thin and soft, and heat produced from the main die 602 can spread to the stacked die 640 relatively fast. The mold compound 608 can be made from thermosetting material, e.g., thermosetting plastic, thermosetting resin, etc., that is in liquid or malleable form at high temperatures and changes irreversibly into infusible and/or insoluble form after being cooled.

In one embodiment, the stacked die 640 and the semiconductor substrate of the main die 602 include substantially the same material. By way of example, the stacked die 640 can be cut from a silicon wafer, e.g., an intact silicon wafer, a cracked silicon wafer, a new wafer, a used wafer having defective circuitry formed thereon, or the like. In addition, as mentioned above, the main die 602 is fabricated from a silicon wafer—that is, the semiconductor substrate of the main die 602 comes from a silicon wafer. In one embodiment, a silicon wafer can include pure silicon or silicon doped with a predetermined amount of impurity atoms such as boron or phosphorus. Thus, as used herein, “substantially the same material” means that the materials of the stacked die 640 and the semiconductor substrate of the main die 602 can have differences because of the differences between the densities and/or types of impurities in the stacked die 640 and the semiconductor substrate of the main die 602, as long as the stacked die 640 and the semiconductor substrate of the main die 602 are made of silicon crystal. Since the stacked die 640 and the main die 602 are made from substantially the same material, their thermal expansion coefficients can be substantially the same. In one embodiment, a bottom surface 642 of the stacked die 640, facing the top surface 616 of the main die 602, can be polished to avoid applying uneven pressure to the top surface 616 of the main die 602.

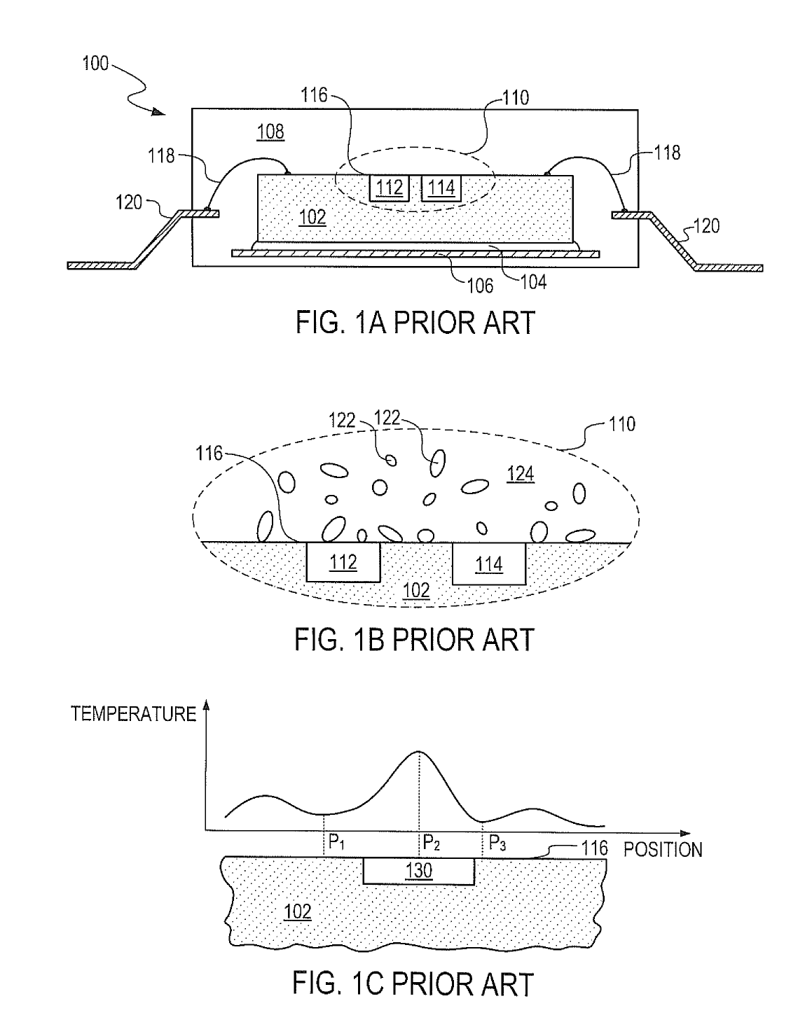

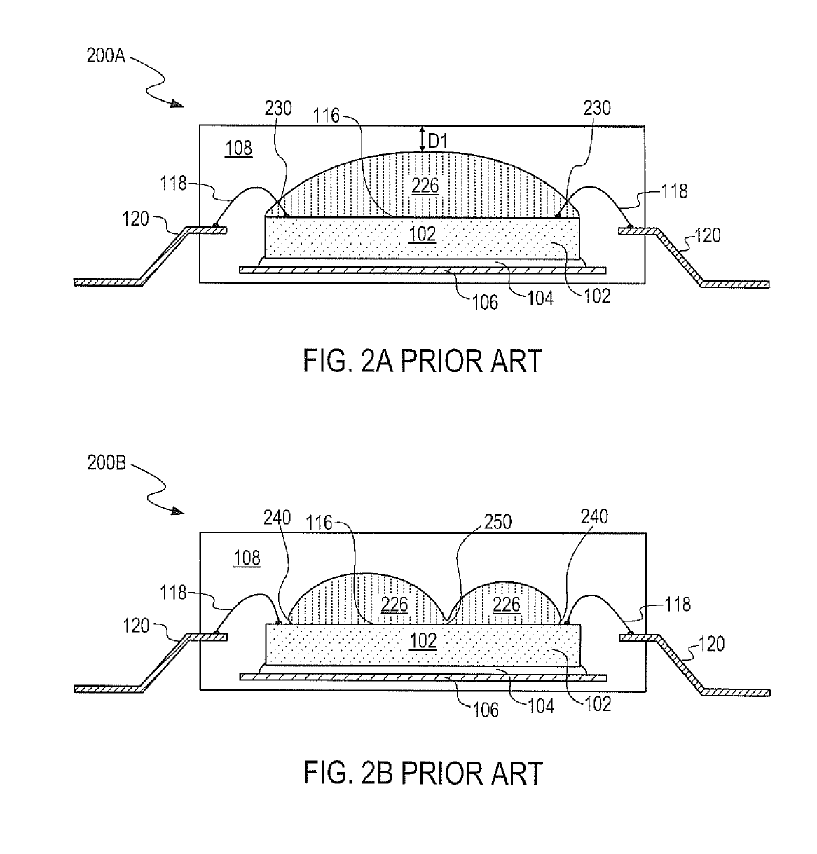

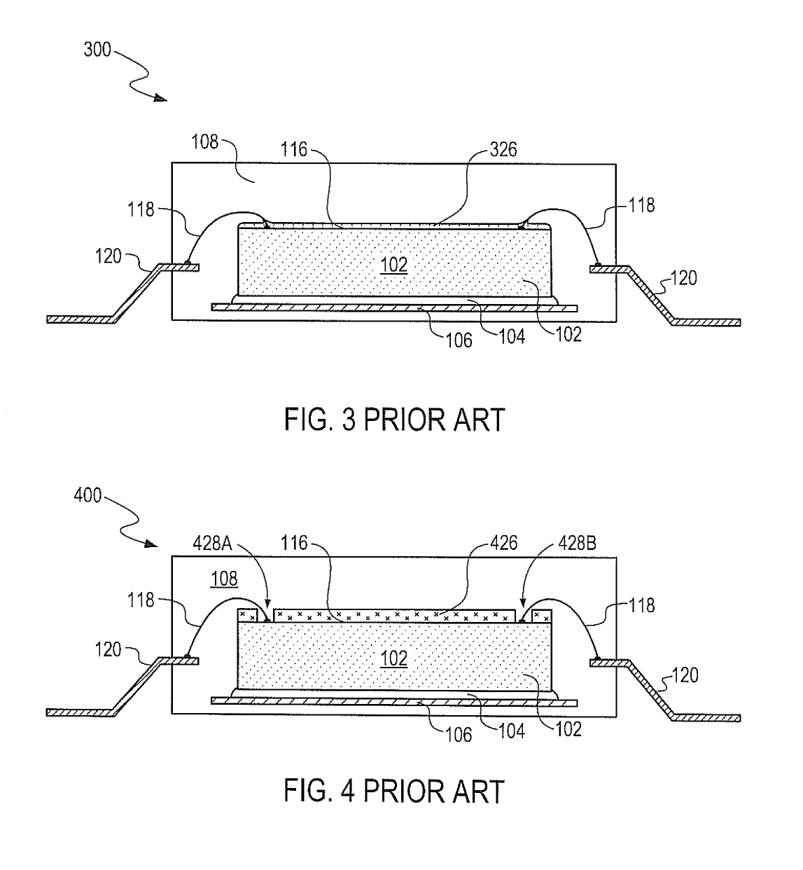

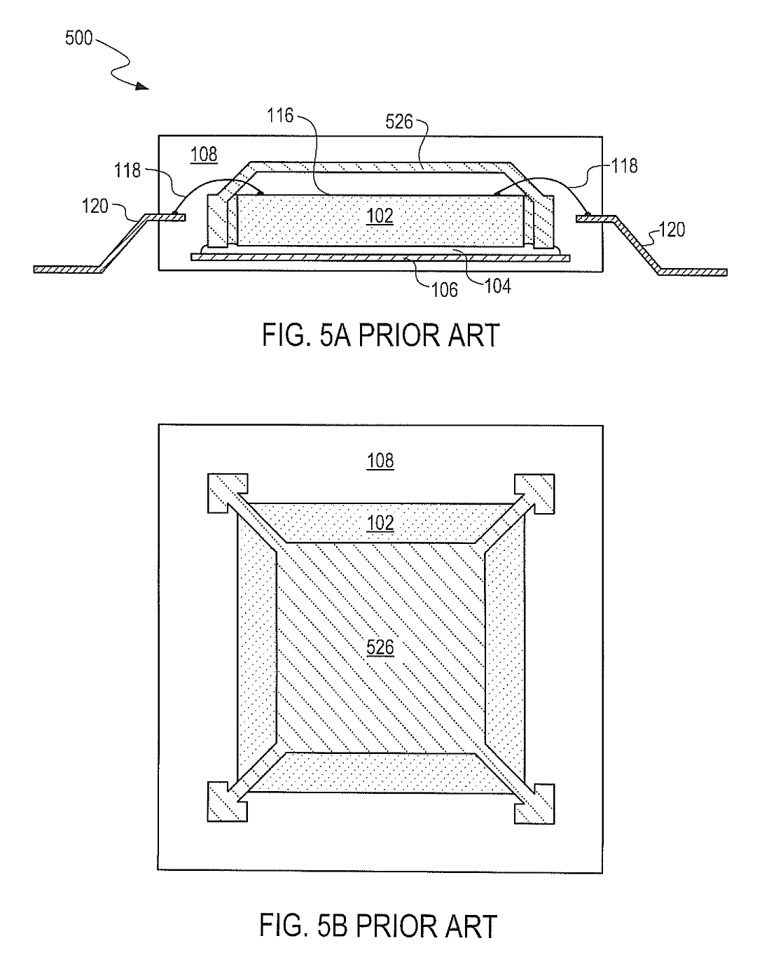

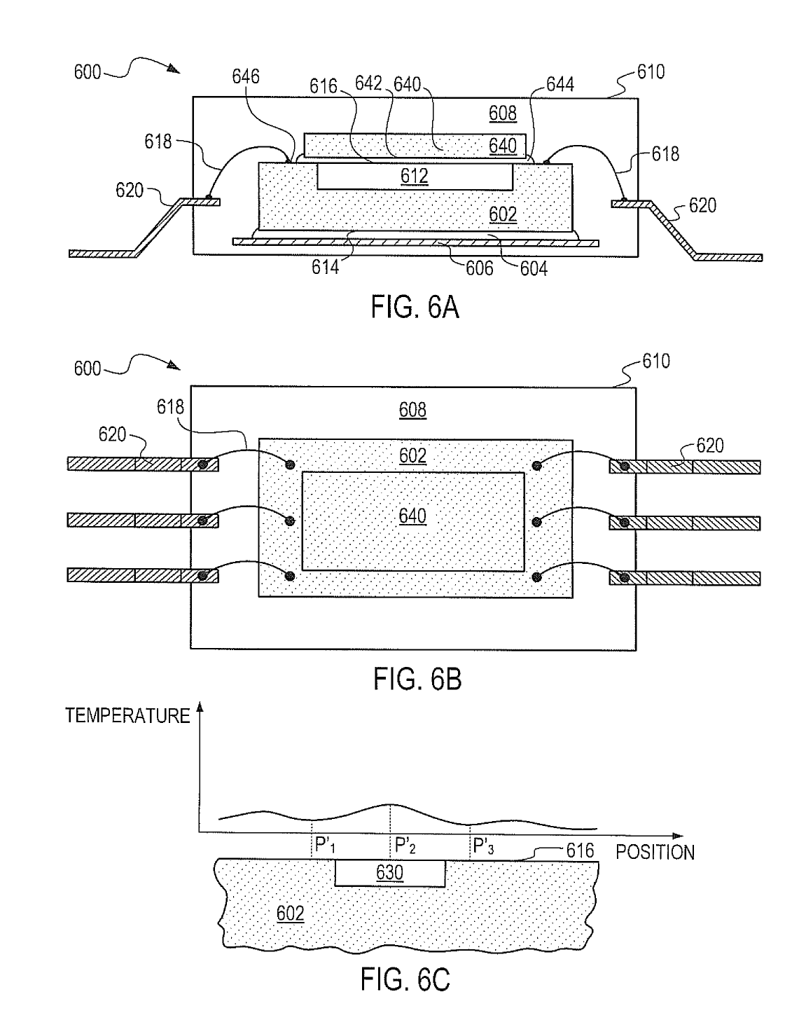

Advantageously, during the encapsulation of the integrated device 600, the stacked die 640 can reduce compression stress and avoid/eliminate shear stress from the mold compound 608 to the top surface 616 of the main die 602. Since the stacked die 640 and the main die 602 can have substantially the same thermal expansion coefficients, and the adhesive film 644 between the stacked die 640 and the main die 602 can be relatively thin and soft, shear stress between the top surface 616 of the main die 602 and the bottom surface 642 of the stacked die 640 is negligible. In one embodiment, the stacked die 640 has a thickness ranging from 30 μm to 350 μm. Due to the rigid structure of silicon crystal, the stacked die 640 can shield the top surface 616 of the main die 602 from the uneven pressure of the harder particles (e.g., particles similar to the particles 122 presented in FIG. 1B) in the mold compound 608. By stacking the stacked die 640 onto the main die 602, the integrated device 600 is more robust. In one embodiment, the stacked die 640 can be obtained by cutting it from, e.g., a cracked silicon wafer or a used wafer having defective circuitry formed thereon. Such a method can be relatively low cost, time saving, and environmentally friendly.

In addition, parameters of sensitive integrated circuitry, e.g., operational amplifiers, band-gap reference circuits, etc., of the integrated device 600 are more stable relative to corresponding parameter values in the conventional integrated device 100. For example, some parameters of the integrated circuitry 612 can remain substantially unchanged before and after the encapsulation. Consequently, the trimming process for those parameters of the integrated circuitry 612 can be omitted from the final test. The additional blocks and conductor pins mentioned in relation to the conventional integrated device 100 can be eliminated from the integrated device 600, and thus the cost and size of the integrated device 600 can be reduced. Moreover, the stacked die 640 can avoid defects caused by the contraction force of the mold compound 608 and the uneven pressure of the harder particles in the mold compound 608. Therefore, the stacked die 640 can improve/enhance the fabrication quality and reliability of the integrated device 600, and also shorten the time for the final test.

Furthermore, since the stacked die 640 is made of silicon crystal, the stacked die 640 has a relatively high thermal conductivity. The stacked die 640 can be used as a heat sink and dissipates heat produced from the main die 602 relatively fast, and can reduce or flatten temperature gradients on the top surface 616 of the main die 602. A plot of examples of temperature gradients at the top surface 616 of the main die 602 is illustrated in FIG. 6C. In the example of FIG. 6C, a circuit 630 in the integrated device 600, similar to the circuit 130 in FIG. 1 C, can be a high-power circuit that produces heat at position P′2 of the top surface 616 during the operation of the integrated circuitry 612. As shown in FIG. 6C, the top surface 616 of the main die 602 has flatter/reduced temperature gradients compared with the temperature gradients shown in FIG. 1C.

The shapes and positions of the conductive pins 620 disclosed in FIG. 6A and FIG. 6B are not intended to limit the package type of the integrated device 600. In one embodiment, the integrated device 600 can be encapsulated in any kind of package, e.g., a ball grid array (BGA), a bumpered quad flat pack (BQFP), a single in-line package (SIP), a small out-line package (SOP), etc. The shape and position of the stacked die 640 shown in FIG. 6B is not intended to be limiting. In one embodiment, the shape and position of the stacked die 640 can be arbitrary, depending on the locations or areas where sensitive integrated circuitry is formed in the main die 602. In addition, although FIG. 6A and FIG. 6B disclose only one stacked die 640, the integrated device 600 in an alternative embodiment may include multiple stacked dies 602 on (e.g., attached/glued) to the top surface 616 of the main die 602. Furthermore, although FIG. 6A discloses only one adhesive film 644 between the stacked die 640 and the main die 602, the stacked die 640 in another embodiment can be attached to the main die 602 using multiple adhesive films. By way of example, a few drops, e.g., relatively small drops, of adhesive material can be deposited on the main die 602, and the few drops of adhesive material can become adhesive films when the stacked die 640 is attached to the main die 602.

FIG. 7A and FIG. 7B illustrate examples of fabrication steps for the integrated device 600, in an embodiment according to the present invention. Although specific steps are disclosed in FIG. 7A and FIG. 7B, such steps are examples. That is, the present invention is well suited to performing various other steps or variations of the steps illustrated in FIG. 7A and FIG. 7B. The fabrication sequence of the integrated device 600 in FIG. 7A and FIG. 7B is for illustrative purposes and is not intended to be limiting. FIG. 7A and FIG. 7B are described in combination with FIG. 6A, FIG. 6B, and FIG. 6C.

In step 702, a silicon wafer 650 is divided into multiple dice, and integrated circuitry is formed on each main die by steps of, e.g., photomasking, etching, diffusion, oxidation, epitaxial growth, deposition, etc. In one embodiment, after the formation of the integrated circuitry, parameters and performance of the integrated circuitry can be tested at the silicon wafer 650. This test can be referred to as a “wafer level test.” Any die that fails can be marked so it can be discarded when the silicon wafer 650 is sawed into individual dice. Thus, after step 702, integrated circuitry 612 is formed on a main die 602, the performance of the integrated circuitry 612 has been tested, and the main die 602 is cut from the silicon wafer 650.

In step 704, the bottom surface 614 of the main die 602 is attached to the die attach pad 606 using, in one embodiment, an adhesive material 604.

In step 706, conductive pins 620 are connected to the integrated circuitry 612 in the main die 602 via, e.g., bonding wires 618 and conductive pads 646.

In step 708, the stacked die 640 is attached to the top surface 616 of the main die 602 using, in one embodiment, an adhesive film 644. In one embodiment, as described above, the stacked die 640 can be cut from a silicon wafer. The bottom surface 642 of the stacked die 640 that faces the top surface 616 of the main die 602 is polished.

In step 710, the die attach pad 606, the main die 602, and the stacked die 640 are encapsulated using the mold compound 608.

In summary, according to embodiments of the present invention, in fabrication processes of integrated devices, stacked dice, e.g., cut from silicon wafers, can be polished and stacked on main dies in the integrated devices. Due to the rigid structure and high thermal conductivity of the stacked dice, contraction forces, uneven pressures, and temperature gradients that exist in the conventional integrated devices can be reduced, eliminated, and flattened, respectively.

While the foregoing description and drawings represent embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

1. An integrated device comprising:
a die attach pad;
a main die having a first surface attached to said die attach pad, having a second surface opposite said first surface, and having circuitry formed therein at said second surface;
a stacked die attached to said second surface using an adhesive film, wherein said main die and said stacked die comprise silicon crystal; and
a mold compound that encapsulates said die attach pad, said main die, and said stacked die, wherein said stacked die shields said circuitry at said second surface from said mold compound.

2. The integrated device as claimed in claim 1, wherein said main die is fabricated from a silicon wafer.

3. The integrated device as claimed in claim 1, wherein said stacked die is cut from a silicon wafer.

4. The integrated device as claimed in claim 1, wherein said stacked die and said main die comprise substantially the same material.

5. The integrated device as claimed in claim 1, wherein said die attach pad comprises a metallic pad.

6. (canceled)

7. The integrated device as claimed in claim 1, wherein said stacked die comprises a surface having been polished and attached to said second surface.

8. The integrated device as claimed in claim 1, wherein said adhesive film comprises electrically non-conductive adhesive material.

9. The integrated device as claimed in claim 1, wherein said mold compound comprises thermosetting material.

10. The integrated device as claimed in claim 1, wherein said stacked die has a thickness in a range from 30 μm to 350 μm.

11-18. (canceled)

19. An integrated device comprising:
a conductive pin connected to circuitry in said integrated device; and
an encapsulated object coupled to said conductive pin, said encapsulated object comprising:
a die attach pad;
a main die having a first surface attached to said die attach pad, having a second surface facing away from said first surface, and having said circuitry formed therein at said second surface;
a stacked die attached to said second surface using an adhesive film, wherein said main die and said stacked die comprise silicon crystal; and
a mold compound that encapsulates said die attach pad, said main die, and said stacked die, wherein said stacked die shields said circuitry at said second surface from said mold compound.

20. The integrated device as claimed in claim 19, wherein said stacked die is cut from a silicon wafer.
